(19) United States
(12) Patent Application Publication
(10) Pub. No.: US 2012/0308919 A1
(43) Pub. Date: Dec. 6, 2012

(54) Manufacturing Method for Color Filter Substrate, Photomask and Photoreactive Layer

(75) Inventors: Hsiao Hsien Chen, Guangdong (CN); Kuan-Cheng Lee, Guangdong (CN)

(73) Assignee: Shenzhen China Star Optoelectronics Technology Co. Ltd., Shenzhen City, Guangdong (CN)

(21) Appl. No.: 13/379,630

(22) PCT Filed: Jul. 22, 2011
(86) PCT No.: PCT/CN11/77471

§ 371 Date: Dec. 20, 2011

(30) Foreign Application Priority Data
Jun. 3, 2011 (CN) 201110149783.6

(51) Int. Cl. G03F 7/20; G02B 5/23; G03F 1/00

(52) U.S. Cl. 430/5; 430/7; 252/586

(57) ABSTRACT

A manufacturing method for a color filter substrate is disclosed in the present disclosure, which comprises the following steps of: providing a substrate; providing a photoreactive layer that covers the substrate; providing a photomask disposed above the photoreactive layer; and providing light rays of different frequency bands for irradiating the photoreactive layer through the photomask so as to form color resist regions and black matrix regions on the photoreactive layer respectively. A photomask and a photoreactive layer for preparing a color resist layer on a color filter substrate are also provided in the present disclosure. Thereby, the present disclosure can advantageously shorten the production cycle, and improve the aperture ratio and the contrast ratio.

### FIELD OF THE INVENTION

The present disclosure generally relates to the technical field of liquid crystal displaying, and more particularly, to a manufacturing method for a color filter substrate, a photomask and a photoreactive layer.

### BACKGROUND OF THE INVENTION

Owing to their advantages such as light weight, thin profile, small size, low power consumption, free of radiation and low manufacturing cost, liquid crystal displays (LCDs) have become a mainstream product in the flat panel display market. The LCDs are very suitable for use in desktop computers, palmtop computers, personal digital assistants (PDAs), mobile phones, TV sets, and various office automation apparatuses and audio & video (AV) apparatuses.

Liquid crystal panels are known as key components of LCDs. Currently, a common liquid crystal panel is formed by a thin-film transistor (TFT) substrate and a color filter (CF) substrate laminated on each other with a liquid crystal layer being sandwiched therebetween. Positional accuracies of red color resist regions, green color resist regions, blue color resist regions and the black matrix (BM) regions on the color filter substrate have an effect on the aperture ratio and the contrast ratio of LCD, consequently, the quality of the display device. In this sense, the manufacturing method of the color resist regions and the black matrix regions on the color filter substrate becomes very important.

Currently, color filter substrates are mostly manufactured through a BM/R/G/B/ITO/PS process flow. However, this process cannot separate the colors through a single exposure; instead, the sequence of coating, exposing and developing steps must be performed repeatedly in order to form resist layers of different colors. And different masks must be formed according to precisions of different machines so that alignment and exposures are performed on the different machines. Because of the precisions of the machines, the aperture ratio is decreased. Furthermore, because a number of layers have to be produced separately, a height difference is caused between areas where BM regions overlap with R/G/B regions and pixel active areas (also termed as AA areas hereinafter), which leads to different tilting angles of liquid crystal molecules; consequently, light leakage occurs and the contrast ratio is degraded.

Therefore, the manufacturing method for the color filter substrate in the prior art is complex and tends to cause degradation in the aperture ratio and the contrast ratio.

Accordingly, an urgent need exists in the art to provide a simplified manufacturing method for a color filter substrate which can improve the aperture ratio and the contrast ratio.

### SUMMARY OF THE INVENTION

A primary objective of the present disclosure is to provide a manufacturing method for a color filter substrate, a photomask and a photoreactive layer, which allow for a simplified manufacturing process and can improve the aperture ratio and the contrast ratio.

To achieve the aforesaid objective, the present disclosure provides a manufacturing method for a color filter substrate, which comprises the following steps of: providing a substrate; providing a photoreactive layer that covers the substrate; providing a photomask disposed above the photoreactive layer; and providing light rays of different frequency bands for irradiating the photoreactive layer through the photomask so as to form color resist regions and black matrix regions on the photoreactive layer respectively.

Preferably, the substrate is a glass substrate.

Preferably, the color resist regions formed on the photoreactive layer include red color resist regions, green color resist regions and blue color resist regions.

Preferably, the red color resist regions, the green color resist regions and the blue color resist regions are arranged in an array on the photoreactive layer, and the black matrix regions are disposed between every two adjacent ones of the color resist regions to isolate the two adjacent color resist regions from each other.

Preferably, the color resist regions and the black matrix regions formed on the photoreactive layer through the irradiation will not experience a change in color again when being irradiated by light rays of other frequency bands.

Preferably, the photomask comprises a plurality of optical band-pass filtering units arranged in an array, and each of the optical band-pass filtering units comprises:
a plurality of first light transmissive regions, each of which selectively transmits light rays of a predetermined frequency band therethrough but blocks light rays of other frequency bands from transmitting therethrough; and
a plurality of second light transmissive regions, being disposed between every two adjacent ones of the first light transmissive regions to isolate the two adjacent first light transmissive regions, and being adapted to allow light rays of a plurality of frequency bands to be transmitted therethrough.

Preferably, the plurality of first light transmissive regions of the photomask include first frequency-band light transmissive regions, second frequency-band light transmissive regions and third frequency-band light transmissive regions, and the manufacturing method further comprises:
providing first frequency-band light rays, second frequency-band light rays and third frequency-band light rays for irradiating the photoreactive layer through the photomask, wherein:
the first frequency-band light transmissive regions only allow the first frequency-band light rays to be transmitted therethrough, and the irradiated regions of the photoreactive layer transform into color resist regions of a first color of the three primary colors red, green and blue through irradiation of the first frequency-band light rays;
the second frequency-band light transmissive regions only allow the second frequency-band light rays to be transmitted therethrough, and the irradiated regions of the photoreactive layer transform into color resist regions of a second color of the three primary colors red, green and blue through irradiation of the second frequency-band light rays;
the third frequency-band light transmissive regions only allow the third frequency-band light rays to be transmitted therethrough, and the irradiated regions of the photoreactive layer transform into color resist regions of a third color of the three primary colors red, green and blue through irradiation of the third frequency-band light rays; and
the irradiated regions of the photoreactive layer transform into the black matrix regions when the first frequency-band light rays, the second frequency-band light rays and the third frequency-band light rays are transmitted through the second light transmissive regions simultaneously.

Preferably, the irradiated regions of the photoreactive layer transform into red color resist regions through irradiation of the first frequency-band light rays, the irradiated regions of the photoreactive layer transform into green color resist regions through irradiation of the second frequency-band light rays, and the irradiated regions of the photoreactive layer transform into blue color resist regions through irradiation of the third frequency-band light rays.

Preferably, single-wavelength laser diodes are used as light sources to provide the desired irradiating light rays.

Preferably, the photomask is an optical band-pass filtering lens array.

To achieve the aforesaid objective, the present disclosure provides a photomask for preparing a color filter substrate, which comprises a plurality of optical band-pass filtering units arranged in an array. Each of the optical band-pass filtering units comprises a plurality of first light transmissive regions, each of which selectively transmits light rays of a predetermined frequency band therethrough; and a plurality of second light transmissive regions, being adapted to allow light rays of a plurality of frequency bands to be transmitted therethrough. The plurality of second light transmissive regions are disposed between every two adjacent ones of the first light transmissive regions to isolate the two adjacent first light transmissive regions.

Preferably, the plurality of first transmissive regions comprise:
first frequency-band light transmissive regions that only allow first frequency-band light rays to be transmitted therethrough;
second frequency-band light transmissive regions that only allow second frequency-band light rays to be transmitted therethrough; and
third frequency-band light transmissive regions that only allow third frequency-band light rays to be transmitted therethrough;
wherein the first frequency-band light rays, the second frequency-band light rays and the third frequency-band light rays can all be transmitted through the second light transmissive regions.

To achieve the aforesaid objective, the present disclosure provides a photoreactive layer for preparing a color resist layer on a color filter substrate. The irradiated regions of the photoreactive layer transform into color resist regions of one color of the three primary colors red, green and blue through irradiation of incident light rays of one of predetermined frequency bands; and the irradiated regions of the photoreactive layer transform into black matrix regions through irradiation of incident light rays of a plurality of the predetermined frequency bands.

Preferably, the incident light rays of the predetermine frequency bands include first frequency-band light rays, second frequency-band light rays and third frequency-band light rays; and
the irradiated regions of the photoreactive layer transform into light transmissive red color resist regions through irradiation of the first frequency-band light rays;
the irradiated regions of the photoreactive layer transform into light transmissive green color resist regions through irradiation of the second frequency-band light rays;
the irradiated regions of the photoreactive layer transform into light transmissive blue color resist regions through irradiation of the third frequency-band light rays; and
the irradiated regions of the photoreactive layer transform into the black matrix regions through simultaneous irradiation of the first frequency-band light rays, the second frequency-band light rays and the third frequency-band light rays.

Preferably, the color resist regions and the black matrix regions formed on the photoreactive layer through the irradiation will not experience a change in color again when being irradiated by light rays of other frequency bands.

As compared to the prior art, the manufacturing method for a color filter substrate according to the present disclosure forms color resist regions and black matrix regions on the photoreactive layer by covering the photoreactive layer on the substrate, disposing the photomask above the photoreactive layer and providing light rays of different frequency bands to irradiate the photoreactive layer. In this way, fabrication of the color resist regions and the black matrix regions can be completed through a single exposure, which simplifies the manufacturing process and shortens the production cycle. Moreover, because preparation of the black matrix layer and the R/G/B color resist layer can be completed through a single exposure, it is unnecessary to consider the exposure precisions of the black matrix layer and the R/G/B color resist layer in the design; thus, the designed aperture ratio can be improved. Furthermore, as the manufacturing process is simplified, the difference in height between regions where the black matrix overlaps the R/G/B color resist layer and the pixel AA regions is decreased, which can further improve the contrast ratio and the light transmissivity.

### BRIEF DESCRIPTION OF THE DRAWINGS

FIG. 1 is a flowchart of a manufacturing method for a color filter substrate according to the present disclosure.

FIG. 2 is a view illustrating steps of the manufacturing method for the color filter substrate according to the present disclosure.

FIG. 3 is a schematic structural view of a photomask according to the present disclosure.

FIG. 4 is a schematic cross-sectional structural view of an optical band-pass filtering unit of the photomask shown in FIG. 3.

FIG. 5 is a schematic structural view of a photoreactive layer according to the present disclosure before being irradiated.

FIG. 6 is a schematic cross-sectional structural view of a color filter substrate formed by irradiating the photoreactive layer according to the present disclosure.

### DETAILED DESCRIPTION OF THE INVENTION

The present disclosure is more particularly described in the following examples that are intended as illustrative only since numerous modifications and variations therein will be apparent to those skilled in the art.

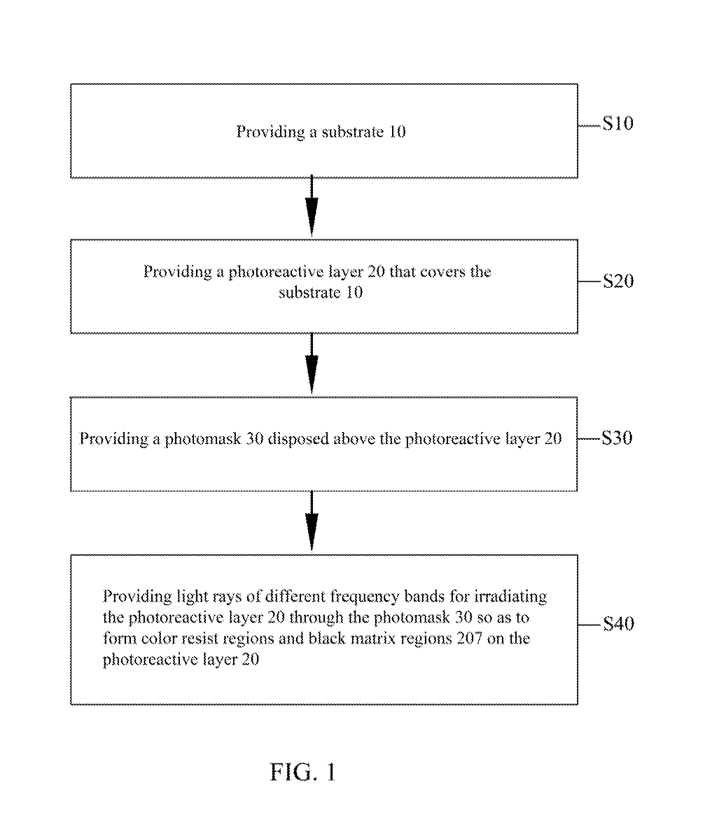

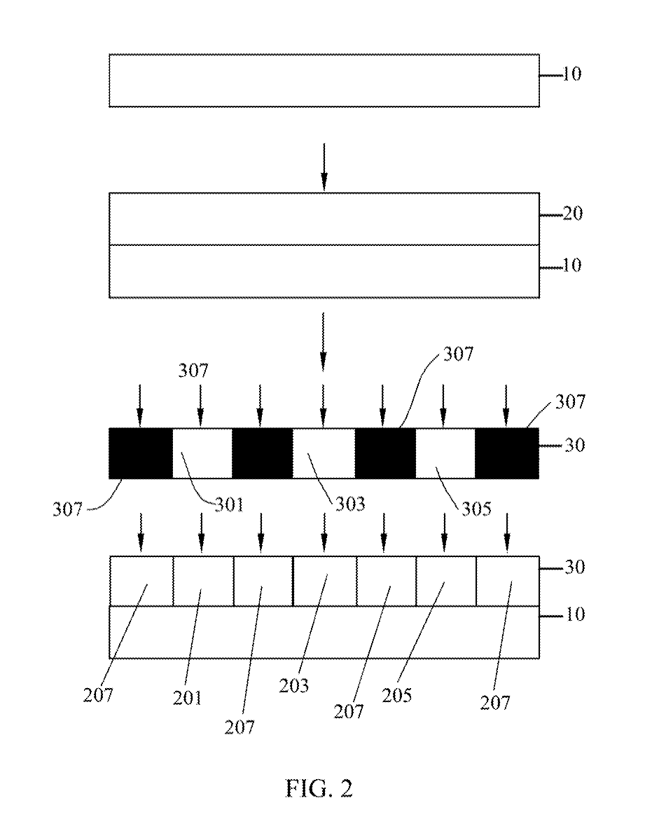

Referring to FIG. 1 and FIG. 2 together, FIG. 1 is a flowchart of a manufacturing method for a color filter substrate according to the present disclosure, and FIG. 2 is a view illustrating steps of the manufacturing method for the color filter substrate according to the present disclosure.

The present disclosure provides a manufacturing method for a color filter substrate, which comprises the following steps:

S10: providing a substrate 10.

In this step, generally a glass substrate is used for the substrate 10. The glass substrate is cleaned of organic or inorganic foreign matters thereon, and a surface thereof is kept flat.

S20: providing a photoreactive layer 20 covering the substrate 10.

In this step, the photoreactive layer 20 is disposed on the surface of the glass substrate 10, and is distributed uniformly and flatly on the glass substrate 20. Regions of different colors can be produced on the photoreactive layer 20 through irradiation of light rays of different frequency bands. That is, in regions of the photoreactive layer 20 that are irradiated by light rays of a same frequency band, color regions of a same color are produced correspondingly; and in regions that are irradiated by light rays of different frequency bands, color regions of different colors are produced. The change in color of the photoreactive layer 20 after being irradiated is irreversible and, after being changed in color, the photoreactive layer 20 becomes stable; i.e., once the photoreactive layer 20 has experienced a change in color due to irradiation of light rays of a certain frequency band, it will never change in color again when being irradiated by light rays of other frequency bands.

S30: providing a photomask 30 disposed above the photoreactive layer 20.

S40: providing light rays of different frequency bands for irradiating the photoreactive layer 20 through the photomask 30 so as to form color resist regions and black matrix regions 207 on the photoreactive layer 20.

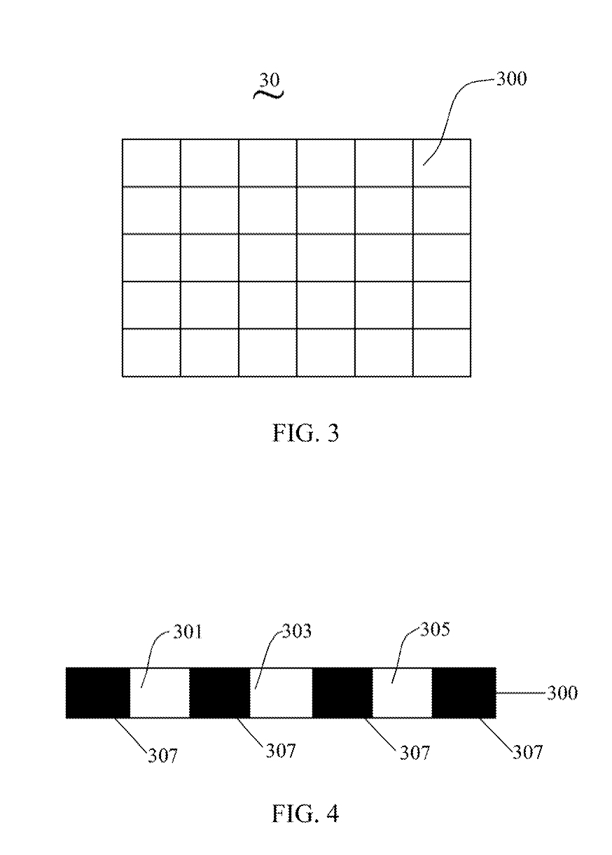

Referring to FIG. 3 and FIG. 4 together, FIG. 3 is a schematic structural view of a photomask 30 according to the present disclosure, and FIG. 4 is a schematic cross-sectional structural view of an optical band-pass filtering unit 300 of the photomask 30 shown in FIG. 3.

Specifically, a photomask 30 is provided in step S30. The photomask 30 comprises a plurality of optical band-pass filtering units 300 arranged in an array, and each of the optical band-pass filtering units 300 comprises a plurality of first light transmissive regions 301, 303 and 305 and a plurality of second light transmissive regions 307. The first light transmissive regions 301, 303 and 305 each selectively transmit light rays of a predetermined frequency band therethrough but block light rays of other frequency bands from transmitting therethrough; and the second light transmissive regions 307 are adapted to allow light rays of a plurality of frequency bands to be transmitted therethrough.

In this embodiment, the first light transmissive regions 301, 303 and 305 include first frequency-band light transmissive regions 301, second frequency-band light transmissive regions 303 and third frequency-band light transmissive regions 305 respectively. The first frequency-band light transmissive regions 301 only allow the first frequency-band light rays to be transmitted therethrough; the second frequency-band light transmissive regions 303 only allow the second frequency-band light rays to be transmitted therethrough; and the third frequency-band light transmissive regions 305 only allow the third frequency-band light rays to be transmitted therethrough.

The plurality of second light transmissive regions 307 are disposed between every two adjacent ones of the first light transmissive regions to isolate the two adjacent first light transmissive regions. The second light transmissive regions 307 are adapted to allow light rays of a plurality of frequency bands to be transmitted therethrough; and specifically, the first frequency-band light rays, the second frequency-band light rays and the third frequency-band light rays can all be transmitted through the second light transmissive regions 307.

In this embodiment, the photomask 30 may be provided as an optical band-pass filtering lens array which comprises a plurality of optical band-pass filtering units arranged in an array and having the same function as the optical band-pass filtering units 300.

In step S40, specifically, a light source comprising the first frequency-band light rays, the second frequency-band light rays and the third frequency-band light rays is provided to irradiate the photoreactive layer 20 through the photomask 30.

The first frequency-band light transmissive regions 301 only allow the first frequency-band light rays to be transmitted therethrough, and the irradiated regions of the photoreactive layer 20 transform into color resist regions of a first color of the three primary colors red, green and blue through irradiation of the first frequency-band light rays. For instance, in this embodiment, the irradiated regions of the photoreactive layer 20 transform into red color resist regions 201 through irradiation of the first frequency-band light rays.

The second frequency-band light transmissive regions 303 only allow the second frequency-band light rays to be transmitted therethrough, and the irradiated regions on the photoreactive layer transform into color resist regions of a second color of the three primary colors red, green and blue through irradiation of the second frequency-band light rays. For instance, in this embodiment, the irradiated regions of the photoreactive layer 20 transform into green color resist regions 203 through irradiation of the second frequency-band light rays.

The third frequency-band light transmissive regions 305 only allow the third frequency-band light rays to be transmitted therethrough, and the irradiated regions of the photoreactive layer 20 transform into color resist regions of a third color of the three primary colors red, green and blue through irradiation of the third frequency-band light rays. For instance, in this embodiment, the irradiated regions of the photoreactive layer 20 transform into blue color resist regions 205 through irradiation of the third frequency-band light rays.

The irradiated regions of the photoreactive layer 20 transform into the black matrix regions 207 when the first frequency-band light rays, the second frequency-band light rays and the third frequency-band light rays are transmitted through the second light transmissive regions 307 simultaneously.

In this embodiment of the present disclosure, the optical band-pass filtering units 300 of the photomask 30 selectively filter the light rays of different frequency bands according to the frequency bands of the light rays, and the photoreactive layer 20 are irradiated by light rays of different frequency bands to form the color resist regions and the black matrix regions 207 on the photoreactive layer 20 correspondingly. The light source may be selected to have a full range of frequency bands, i.e., the first frequency-band light rays, the second frequency-band light rays and the third frequency-band light rays that are needed to induce changes in color of the photoreactive layer 20.

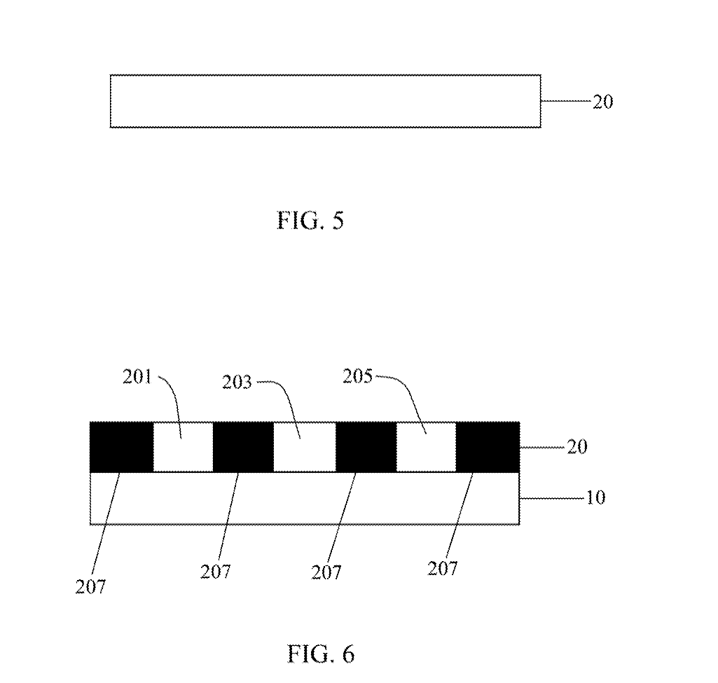

Referring to FIG. 5, there is shown a schematic structural view of the photoreactive layer 20 according to the present disclosure before being irradiated. The photoreactive layer 20 is used to form a color resist layer on a color filter substrate, and has the following characteristics:
color resist regions of one color of the three primary colors red, green and blue may be formed on the photoreactive layer 20 through irradiation of incident light rays of one of predetermined frequency bands; and
black matrix regions may be formed on the photoreactive layer 20 through irradiation of incident light rays of a plurality of the predetermined frequency bands.

Referring to FIG. 6, there is shown a schematic cross-sectional structural view of a color filter substrate formed by irradiating the photoreactive layer according to the present disclosure.

Specifically, the incident light rays of the predetermine frequency bands include first frequency-band light rays, second frequency-band light rays and third frequency-band light rays. The first frequency-band light rays, the second frequency-band light rays and the third frequency-band light rays irradiate the photoreactive layer 20 through the photomask 30. The optical band-pass filtering units 300 of the photomask 30 function to selectively transmit the incident light rays therethrough according to frequency bands of the incident light rays.

The first frequency-band light transmissive regions 301 only allow the first frequency-band light rays to be transmitted therethrough, and the irradiated regions of the photoreactive layer 20 transform into the red transmissive color resist regions 201 through irradiation of the first frequency-band light rays;
the second frequency-band light transmissive regions 303 only allow the second frequency-band light rays to be transmitted therethrough, and the irradiated regions of the photoreactive layer 20 transform into the green transmissive color resist regions 203 through irradiation of the second frequency-band light rays;
the third frequency-band light transmissive regions 305 only allow the third frequency-band light rays to be transmitted therethrough, and the irradiated regions of the photoreactive layer 20 transform into the blue transmissive color resist regions 205 through irradiation of the third frequency-band light rays.

That is, the irradiated regions of the photoreactive layer 20 transform into color resist regions 201, 203 or 205 of a single color when the photoreactive layer 20 is irradiated by light rays of a predetermined frequency band; and the irradiated regions of the photoreactive layer 20 transform into the black matrix regions 207 when the photoreactive layer 20 is irradiated by the first frequency-band light rays, the second frequency-band light rays and the third frequency-band light rays simultaneously.

In this step, a light source comprising light rays of a full range of frequency bands can be used to irradiate the photomask 30, and then according to frequency bands thereof, the light rays are selectively transmitted through the optical band-pass filtering units 300 of the photomask 30 to irradiate the photoreactive layer 20.

Furthermore, other embodiments of the present disclosure are also possible. For instance, in the first frequency-band light transmissive regions 301, the second frequency-band light transmissive regions 303 and the third frequency-band light transmissive regions 305 of the first light transmissive regions of the photomask 30, single-wavelength laser diodes capable of emitting the first frequency-band light rays, the second frequency-band light rays and the third frequency-band light rays are disposed as light sources respectively to irradiate the photoreactive layer 20; and in the second light transmissive regions 307 of the photomask 30, single-wavelength laser diodes capable of emitting the first frequency-band light rays, the second frequency-band light rays and the third frequency-band light rays simultaneously are disposed as light sources to irradiate the second light transmissive regions 307.

As compared to the prior art, the present disclosure forms color resist regions and black matrix regions by irradiating the photoreactive layer 20 coated on the substrate 10, disposing the photomask 30 above the photoreactive layer 20 and providing light rays of different frequency bands to irradiate the photoreactive layer 20 through the photomask 30. In this way, fabrication of the color resist regions and the black matrix regions 207 can be completed through a single exposure, which simplifies the manufacturing process and shortens the production cycle. Moreover, because the black matrix layer and the R/G/B color resist layer can be completed through a single exposure, it is unnecessary to consider the exposure precisions of the black matrix layer and the R/G/B color resist layer in the design; thus, the designed aperture ratio can be improved. Furthermore, as the manufacturing process is simplified, the difference in height between regions where the black matrix overlaps the R/G/B color resist layer and the pixel AA regions is decreased, which can further improve the contrast ratio and the light transmissivity.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A manufacturing method for a color filter substrate, comprising the following steps of:
providing a substrate;
providing a photoreactive layer that covers the substrate;
providing a photomask disposed above the photoreactive layer; and
providing light rays of different frequency bands for irradiating the photoreactive layer through the photomask so as to form color resist regions and black matrix regions on the photoreactive layer respectively.

2. The manufacturing method of claim 1, wherein the substrate is a glass substrate.

3. The manufacturing method of claim 1, wherein the color resist regions formed on the photoreactive layer include red color resist regions, green color resist regions and blue color resist regions.

4. The manufacturing method of claim 3, wherein the red color resist regions, the green color resist regions and the blue color resist regions are arranged in an array on the photoreactive layer, and the black matrix regions are disposed between every two adjacent ones of the color resist regions to isolate the two adjacent color resist regions from each other.

5. The manufacturing method of claim 1, wherein the color resist regions and the black matrix regions formed on the photoreactive layer through the irradiation will not experience a change in color again when being irradiated by light rays of other frequency bands.

6. The manufacturing method of claim 1, wherein the photomask comprises a plurality of optical band-pass filtering units arranged in an array, and each of the optical band-pass filtering units comprises:
a plurality of first light transmissive regions, each of which selectively transmits light rays of a predetermined frequency band therethrough but blocks light rays of other frequency bands from transmitting therethrough; and
a plurality of second light transmissive regions, being disposed between every two adjacent ones of the first light transmissive regions to isolate the two adjacent first light transmissive regions, and being adapted to allow light rays of a plurality of frequency bands to be transmitted therethrough.

7. The manufacturing method of claim 6, wherein the plurality of first light transmissive regions of the photomask include first frequency-band light transmissive regions, second frequency-band light transmissive regions and third frequency-band light transmissive regions, the manufacturing method further comprising:
providing first frequency-band light rays, second frequency-band light rays and third frequency-band light rays for irradiating the photoreactive layer through the photomask, wherein:
the first frequency-band light transmissive regions only allow the first frequency-band light rays to be transmitted therethrough, and the irradiated regions of the photoreactive layer transform into color resist regions of a first color of the three primary colors red, green and blue through irradiation of the first frequency-band light rays;
the second frequency-band light transmissive regions only allow the second frequency-band light rays to be transmitted therethrough, and the irradiated regions of the photoreactive layer transform into color resist regions of a second color of the three primary colors red, green and blue through irradiation of the second frequency-band light rays;
the third frequency-band light transmissive regions only allow the third frequency-band light rays to be transmitted therethrough, and the irradiated regions of the photoreactive layer transform into color resist regions of a third color of the three primary colors red, green and blue through irradiation of the third frequency-band light rays; and
the irradiated regions of the photoreactive layer transform into the black matrix regions when the first frequency-band light rays, the second frequency-band light rays and the third frequency-band light rays are transmitted through the second light transmissive regions simultaneously.

8. The manufacturing method of claim 7, wherein the irradiated regions of the photoreactive layer transform into red color resist regions through irradiation of the first frequency-band light rays, the irradiated regions of the photoreactive layer transform into green color resist regions through irradiation of the second frequency-band light rays, and the irradiated regions of the photoreactive layer transform into blue color resist regions through irradiation of the third frequency-band light rays.

9. The manufacturing method of claim 1, wherein single-wavelength laser diodes are used as light sources to provide the desired irradiating light rays.

10. The manufacturing method of claim 1, wherein the photomask is an optical band-pass filtering lens array.

11. A photomask for preparing a color filter substrate, comprising a plurality of optical band-pass filtering units arranged in an array, each of the optical band-pass filtering units comprises:
a plurality of first light transmissive regions, each of which selectively transmits light rays of a predetermined frequency band therethrough; and
a plurality of second light transmissive regions, being adapted to allow light rays of a plurality of frequency bands to be transmitted therethrough;
wherein the plurality of second light transmissive regions are disposed between every two adjacent ones of the first light transmissive regions to isolate the two adjacent first light transmissive regions.

12. The photomask of claim 11, wherein the plurality of first transmissive regions comprises:
first frequency-band light transmissive regions that only allow first frequency-band light rays to be transmitted therethrough;
second frequency-band light transmissive regions that only allow second frequency-band light rays to be transmitted therethrough; and
third frequency-band light transmissive regions that only allow third frequency-band light rays to be transmitted therethrough;
wherein the first frequency-band light rays, the second frequency-band light rays and the third frequency-band light rays can all be transmitted through the second light transmissive regions.

13. A photoreactive layer for preparing a color resist layer on a color filter substrate, wherein:
the irradiated regions of the photoreactive layer transform into color resist regions of one color of the three primary colors red, green and blue through irradiation of incident light rays of one of predetermined frequency bands; and
the irradiated regions of the photoreactive layer transform into black matrix regions through irradiation of incident light rays of a plurality of the predetermined frequency bands.

14. The photoreactive layer of claim 13, wherein:
the incident light rays of the predetermine frequency bands include first frequency-band light rays, second frequency-band light rays and third frequency-band light rays;
the irradiated regions of the photoreactive layer transform into light transmissive red color resist regions through irradiation of the first frequency-band light rays;
the irradiated regions of the photoreactive layer transform into light transmissive green color resist regions through irradiation of the second frequency-band light rays;
the irradiated regions of the photoreactive layer transform into light transmissive blue color resist regions through irradiation of the third frequency-band light rays; and
the irradiated regions of the photoreactive layer transform into the black matrix regions through simultaneous irradiation of the first frequency-band light rays, the second frequency-band light rays and the third frequency-band light rays.

15. The photoreactive layer of claim 13, wherein the color resist regions and the black matrix regions formed on the photoreactive layer through the irradiation will not experience a change in color again when being irradiated by light rays of other frequency bands.
